(19) United States
(12) Patent Application Publication
(10) Pub. No.: US 2012/0061739 A1
(43) Pub. Date: Mar. 15, 2012

(54) METHOD FOR FABRICATING CAPACITOR AND SEMICONDUCTOR DEVICE USING THE SAME

(75) Inventors: Hyun Seok KIM, Icheon-si (KR); Jun Ho LEE, Seongnam-si (KR); Boo Ho JUNG, Icheon-si (KR); Sun Ki CHO, Icheon-si (KR); Yang Hee KIM, Icheon-si (KR); Young Won KIM, Icheon-si (KR)

(73) Assignee: HYNIX SEMICONDUCTOR INC., Icheon-si (KR)

(21) Appl. No.: 13/034,038

(22) Filed: Feb. 24, 2011

(30) Foreign Application Priority Data
Sep. 10, 2010 (KR) 10-2010-0089112

(51) Int. Cl. H01L 29/94; H01L 21/8242

(52) U.S. Cl. 257/296; 438/239; 257/E29.345; 257/E21.647

(57) ABSTRACT

Provided are a method for fabricating a capacitor and a semiconductor device using the same. The semiconductor device includes a MOS transistor capacitor, first and second plate capacitors, and a metal interconnection. The MOS transistor capacitor is arranged between a power supply and a ground. The first and second plate capacitors are arranged between the power supply and the ground. The metal interconnection is configured to connect the first and second plate capacitors.

### CROSS-REFERENCES TO RELATED APPLICATIONS

The present application claims priority under 35 U.S.0 119(a) to Korean Application No. 10-2010-0089112, filed on Sep. 10, 2010, in the Korean intellectual property Office, which is incorporated herein by reference in its entirety set forth in full.

### BACKGROUND

Semiconductor devices may include capacitors for stable voltage supply and transmission/reception (TX/RX) signal stability. In particular, semiconductor devices may include decoupling capacitors that has a good effect in reducing a voltage/signal change due to a noise. A decoupling capacitor is arranged between an internal circuit and a signal transmission line or between the internal circuit and a voltage supply line, and is used as a temporary current source to reduce a noise. That is, the decoupling capacitor supplies a current to the internal circuit when a sudden voltage drop occurs, thereby compensating the noise and the voltage drop.

The decoupling capacitor is connected through a first contact CT1, and is arranged between a power supply VDD and a ground VSS to reduce a power supply voltage (VDD) noise. Because the first contact CT1 is narrowed and lengthened due to the high integration of semiconductor memory devices, it may be formed of polysilicon having good gap-fill characteristics.

However, the first contact CT1 formed of polysilicon has a high resistance when the power supply voltage (VDD) has a high frequency. Accordingly, the decoupling capacitor may fail to suitably transmit a power noise to the ground VSS, thus failing to filter the high frequency of the power supply voltage VDD. This degrades the noise elimination efficiency of the decoupling capacitor.

### SUMMARY

An embodiment of the present invention is directed to a semiconductor device that improves the noise elimination efficiency of a decoupling capacitor by reducing the interconnection resistance of the decoupling capacitor.

In an exemplary embodiment of the present invention, a semiconductor device includes a MOS transistor capacitor arranged between a power supply and a ground, first and second plate capacitors arranged between the power supply and the ground, and a metal interconnection configured to connect the first and second plate capacitors.

In another exemplary embodiment of the present invention, a method for fabricating a capacitor includes forming a MOS transistor capacitor in a semiconductor substrate, forming an interlayer dielectric on the MOS transistor capacitor, forming a metal interconnection on the interlayer dielectric, and forming first and second plate capacitors connected by the metal interconnection, after the forming of the metal interconnection.

### BRIEF DESCRIPTION OF THE DRAWINGS

The above and other aspects, features and other advantages will be more clearly understood from the following detailed description taken in conjunction with the accompanying drawings, in which:

FIG. 1 is a perspective view of a semiconductor device according to an exemplary embodiment of the present invention;

FIG. 2 is an equivalent circuit diagram of a semiconductor device according to an exemplary embodiment of the present invention; and

FIG. 3 is a graph illustrating the resistance between a polysilicon layer and a metal layer within the same high frequency band.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

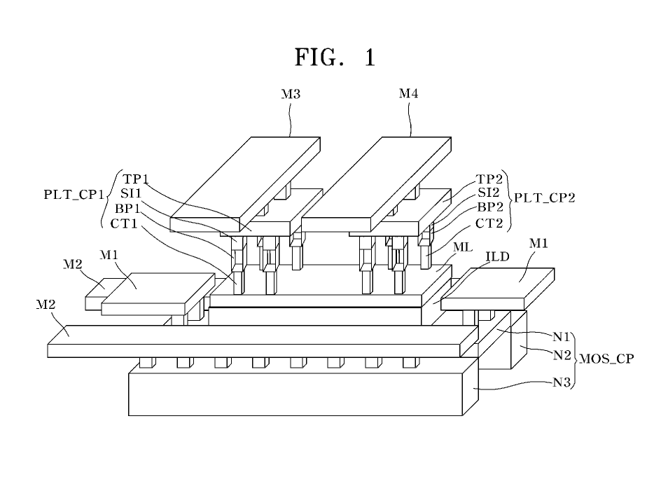

FIG. 1 is a perspective view of a semiconductor device according to an exemplary embodiment of the present invention.

Referring to FIG. 1, a semiconductor device includes a MOS transistor capacitor MOS_CP, an interlayer dielectric ILD, a metal interconnection ML, and first and second plate capacitors PLT_CP1 and PLT_CP2.

The MOS transistor capacitor MOS_CP includes a gate N1, a source N2, and a drain N3.

The MOS transistor capacitor MOS_CP is formed by forming a gate (N1) electrode on a semiconductor substrate to form a gate (N1) region, and implanting impurity ions into the semiconductor substrate except the gate (N1) region to form a source N2 and a drain N3. Here, the gate (N1) electrode may be formed of polysilicon. Next, a dielectric layer having contact holes is formed on the gate N1, the source N2 and the drain N3. Here, the dielectric layer may be formed of silicon oxide. Also, a first interconnection M1 fills the contact hole of the gate N1 to connect the gate N1 and the power supply VDD, and a second interconnection M2 fills the contact holes of the source N2 and the drain N3 to connect the source N2 and the drain N3 in common to the ground VSS. Herein, the MOS transistor capacitor MOS_CP may be an NMOS transistor.

The interlayer dielectric ILD may be formed of a silicon oxide on the MOS transistor capacitor MOS_CP.

The metal interconnection ML may be a plate-type metal layer on the interlayer dielectric ILD.

The first plate capacitor PLT_CP1 includes a first contact CT1, a first bottom electrode BP1, a first dielectric layer SI1, and a first top electrode TP1.

The first plate capacitor PLT_CP1 is formed by forming a first contact CT1 on the metal interconnection ML, forming a first bottom electrode BP1 on the first contact CT1, forming a first dielectric layer SI1 on the first bottom electrode BP1, and forming a first top electrode TP1 on the first dielectric layer SI1. Here, the first contact CT1 is connected to the metal interconnection ML, and the power supply voltage VDD is applied through a third interconnection M3 to the first top electrode TP1.

The second plate capacitor PLT_CP2 includes a second contact CT2, a second bottom electrode BP2, a second dielectric layer SI2, and a second top electrode TP2.

The second plate capacitor PLT_CP2 is formed by forming a second contact CT2 on the metal interconnection ML, forming a second bottom electrode BP2 on the second contact CT2, forming a second dielectric layer SI2 on the second bottom electrode BP2, and forming a second top electrode TP2 on the second dielectric layer SI2.

Here, the second contact CT2 is connected to the metal interconnection ML, and the ground voltage VSS is applied through a fourth interconnection M4 to the second top electrode TP2.

The first plate capacitor PLT_CP1 and the second plate capacitor PLT_CP2 are formed of the same materials under the same process conditions.

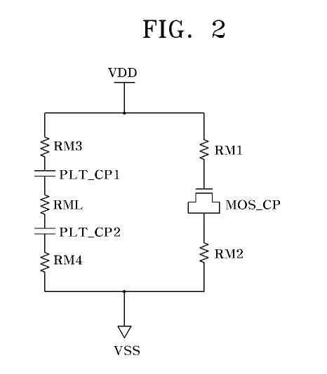

FIG. 2 is an equivalent circuit diagram of the semiconductor device according to an exemplary embodiment of the present invention.

Referring to FIG. 2, if the first and second plate capacitors PLT_CP1 and PLT_CP2 are connected by the metal interconnection ML, an interconnection resistance RML becomes smaller than a polysilicon interconnection. Therefore, even when the power supply voltage VDD is applied at a high frequency, a high-frequency noise contained in the power supply voltage VDD may be effectively transmitted to the first and second plate capacitors PLT_CP1 and PLT_CP2. Accordingly, the first and second plate capacitors PLT_CP1 and PLT_CP2 effectively transmit the high-frequency power supply voltage (VDD) to the ground VSS, thus reducing the high-frequency noise.

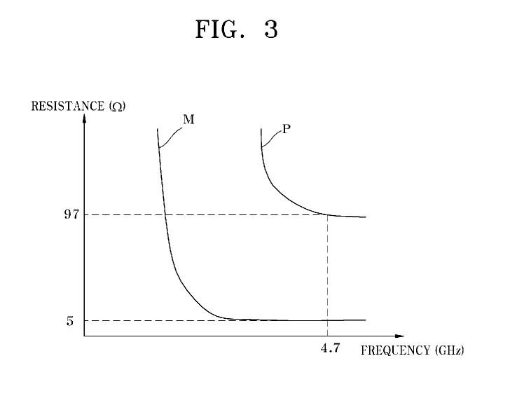

FIG. 3 is a graph illustrating the resistance between a polysilicon layer and a metal layer within the same high frequency band.

Referring to FIG. 3, in a 4.7 GHz frequency band, a polysilicon layer has a resistance of approximately 97 Ω and a metal layer M has a resistance of approximately 5 Ω. That is, in the same high-frequency band, the metal layer M has an approximately 20 times lower resistance than the polysilicon layer P.

As described above, by forming the metal interconnection ML between the first and second plate capacitors PLT_CP1 and PLT_CP2 to connect the first and second plate capacitors PLT_CP1 and PLT_CP2, the power supply voltage VDD containing a high-frequency noise may be effectively transmitted to the first and second plate capacitors PLT_CP1 and PLT_CP2, and the first and second plate capacitors PLT_CP1 and PLT_CP2 may transmit the high-frequency nose of the power supply voltage (VDD) to the ground VSS, thus improving the efficiency of reducing the high-frequency noise of the power supply voltage VDD.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A semiconductor device comprising:
a MOS transistor capacitor arranged between a power supply and a ground;
first and second plate capacitors arranged between the power supply and the ground; and
a metal interconnection configured to connect the first and second plate capacitors.

2. The semiconductor device of claim 1, wherein the metal interconnection is a plate type metal layer.

3. The semiconductor device of claim 1, wherein the MOS transistor capacitor has a gate, a source, and a drain.

4. The semiconductor device of claim 3, wherein a power supply voltage of the power supply is applied to the gate, and a ground voltage of the ground is applied to the source and the drain.

5. The semiconductor device of claim 1, wherein the MOS transistor capacitor is an NMOS transistor.

6. The semiconductor device of claim 1, wherein the first plate capacitor comprises:
a first contact connected to the metal interconnection;
a first bottom electrode formed on the first contact;
a first dielectric layer formed on the first bottom electrode; and
a first top electrode formed on the first dielectric layer.

7. The semiconductor device of claim 1, wherein the second plate capacitor comprises:
a second contact connected to the metal interconnection;
a second bottom electrode formed on the second contact;
a second dielectric layer formed on the second bottom electrode; and
a second top electrode formed on the second dielectric layer.

8. The semiconductor device of claim 6, wherein the power supply voltage is applied to the first top electrode, and the ground voltage is applied to the second top electrode.

9. A method for fabricating a capacitor, comprising:
forming a MOS transistor capacitor in a semiconductor substrate;
forming an interlayer dielectric on the MOS transistor capacitor;
forming a metal interconnection on the interlayer dielectric; and
forming first and second plate capacitors connected by the metal interconnection.

10. The method of claim 9, wherein the metal interconnection comprises a plate type metal layer.

11. The method of claim 9, wherein the forming of the MOS transistor capacitor comprises:
forming a gate by forming a polysilicon layer on the semiconductor substrate; and
implanting impurity ions into the semiconductor substrate to form a source and a drain.

12. The method of claim 9, wherein the forming of the first plate capacitor comprises:
forming a first contact on the metal interconnection;
forming a first bottom electrode on the first contact;
forming a first dielectric layer on the first bottom electrode; and
forming a first top electrode on the first dielectric layer.

13. The method of claim 9, wherein the forming of the second plate capacitor comprises:
forming a second contact on the metal interconnection;
forming a second bottom electrode on the second contact;
forming a second dielectric layer on the second bottom electrode; and
forming a second top electrode on the second dielectric layer.

14. The method of claim 9, wherein the first and second plate capacitors are formed of the same materials under the same process conditions.

15. The method of claim 9, wherein the first and second plate capacitors are formed after the forming of the metal interconnection, and a first contact of the first plate capacitor and a second contact of the second plate capacitor are connected to the metal interconnection.
